(19) United States
(12) Patent Application Publication
(10) Pub. No.: US 2026/0197960 A1
(43) Pub. Date: Jul. 9, 2026

(54) CABINET AND SERVER

(71) Applicant: Fulian Precision Electronics (Tianjin) Co., LTD., Tianjin (CN)

(72) Inventors: LIANG GAO, Tianjin (CN); XIAO-LI YAN, Tianjin (CN); FANG-XING YANG, Tianjin (CN); YA-NI ZHANG, Tianjin (CN); WEN-TZU CHEN, New Taipei (TW); QING-SONG ZENG, New Taipei (TW); CHEN-HAO SU, New Taipei (TW); XIANG-YU LEI, New Taipei (TW); LI-PING CHEN, New Taipei (TW); HONG-ZHANG LIN, New Taipei (TW)

(21) Appl. No.: 19/312,641

(22) Filed: Aug. 28, 2025

(30) Foreign Application Priority Data
Jan. 9, 2025 (CN) 202510047294.1

(51) Int. Cl. H05K 7/14; H05K 5/02; H05K 5/03; H05K 7/20

(52) U.S. Cl. CPC H05K 7/1489; H05K 5/0221; H05K 5/023; H05K 5/03; H05K 7/20172; H05K 7/20145

(57) ABSTRACT

A cabinet for a server includes a chassis with a chamber and an opening, a bracket slidable into or out of the chamber through the opening, and a cover rotatably mounted on the bracket. The bracket forms a lower room, an upper front room, and an upper rear room, with the lower room and upper front room configured to hold hardware and the upper rear room configured to hold a fan. When the bracket is slid out of the chamber, the cover can be rotated to open the upper rear room, allowing the fan to be detached for maintenance. When the cover is closed, the bracket can be slid back into the chamber. This design facilitates convenient fan maintenance without disassembling the cabinet.

### FIELD

The disclosure herein generally relates to information computing systems, and more particularly relates to a cabinet and a server.

### BACKGROUND

Servers are usually equipped with a fan, and the fan sometimes needs to be removed from the server for maintenance or replacement. However, due to the compact structure of the server, removing the fan requires disassembling the server's chassis to take out the fan, which is complex and time-consuming.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of a portion of a server and a cabinet in an embodiment of the present application.

FIG. 2 is an isometric view of the cabinet in FIG. 1 when a bracket is slid into a chamber.

FIG. 3 is an isometric view of the cabinet in FIG. 2 when the bracket is slid out of the chamber.

FIG. 4 is an isometric view of the cabinet in FIG. 3 after a fan is removed from an upper rear room.

FIG. 5 is an exploded view of the cabinet in FIG. 4.

FIG. 6 is an isometric view of a front bracket part in FIG. 5, viewed from a bottom perspective.

FIG. 7 is an isometric view of the front bracket part in FIG. 6, viewed from a top perspective.

FIG. 8 is an isometric view of a rear bracket part in FIG. 5, viewed from a rear perspective.

FIG. 9 is an enlarged view of the area labeled A in FIG. 5.

FIG. 10 is an isometric view of a handle of a cabinet in an embodiment of the present application.

FIG. 11 is an isometric view of the cabinet in FIG. 10 with a chassis removed at the handle.

FIG. 12 is an isometric view of the structure in FIG. 11, viewed from a top perspective.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

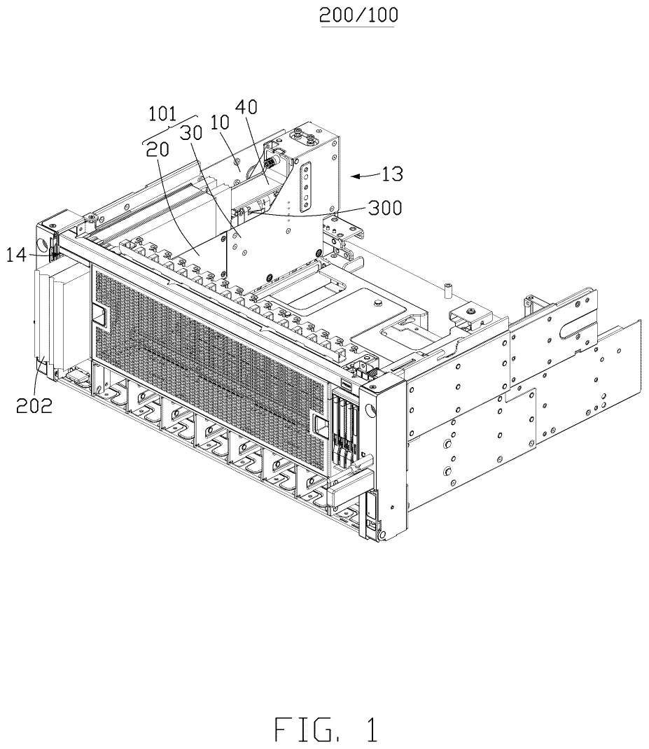

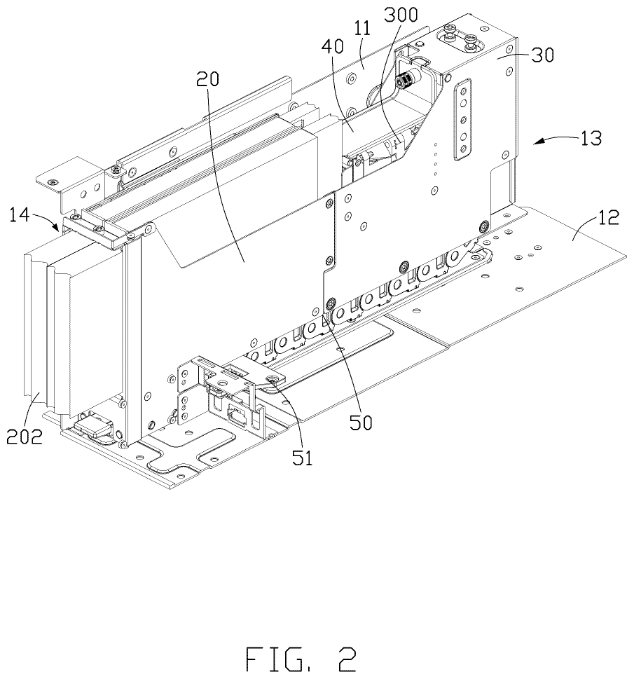

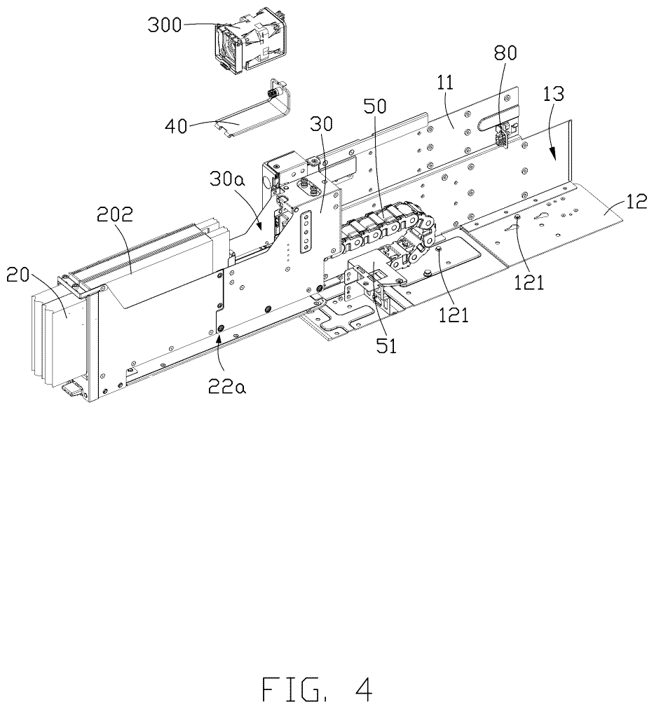

As shown in FIGS. 1 to 4, an embodiment of the present application provides a server 200, and the server 200 includes a cabinet 100 and a fan 300. The cabinet 100 includes a chassis 10 and a bracket 101. The bracket 101 includes a front bracket part 20 and a rear bracket part 30. The chassis 10 includes a wall 11 and a floor 12 that are perpendicularly connected. A chamber 13 is formed inside the chassis 10 adjacent to the wall 11, and an opening 14 communicating with the chamber 13 is provided on the front side of the chassis 10. The front bracket part 20 is slidably mounted on the floor 12, and the front bracket part 20 can slide out of or into the chamber 13 through the opening 14. The front bracket part 20 forms a lower room 20a and an upper front room 20b, with the upper front room 20b located above the lower room 20a. The lower room 20a is used for accommodating expansion cards 201, and the upper front room 20b is used for accommodating hard drives 202, with the hard drives 202 plugged into the expansion cards 201. The rear bracket part 30 is fixedly installed on the front bracket part 20, and the rear bracket part 30 forms an upper rear room 30a used for installing the fan 300. The upper rear room 30a is located above the lower room 20a and behind the upper front room 20b. The top of the rear bracket part 30 is provided with a cover 40, which can be flipped relative to the rear bracket part 30 to open or cover the upper rear room 30a, thereby allowing the fan 300 to enter or exit the upper rear room 30a.

As an exemplary illustration, the expansion cards 201 are Riser cards, which can provide additional slots on the motherboard of the server 200, enabling the server 200 to connect more hard drives 202. The hard drives 202 are PCIe (peripheral component interconnect express) cards, which are a high-speed, high-bandwidth serial interconnect technology specifically designed for connecting various peripherals on the computer motherboard, such as graphics cards, sound cards, network cards, or hard drives.

When the fan 300 inside the cabinet 100 needs to be removed, the user only needs to manually pull out the front bracket part 20. The rear bracket part 30 slides out of the chamber 13 along with the front bracket part 20. After sliding out, the cover 40 is located outside the opening 14. The user then opens the cover 40 to access the upper rear room 30a and removes the fan 300 from the upper rear room 30a.

When the fan 300 needs to be reinstalled into the cabinet 100, the user places the repaired fan 300 back into the upper rear room 30a, closes the cover 40, and pushes the front bracket part 20 back. The rear bracket part 30 slides into the chamber 13 along with the front bracket part 20. After sliding fully into place, the fan 300 and the expansion cards 201 are automatically plugged into the motherboard of the cabinet 100. In summary, the cabinet 100 enhances the convenience of installing and removing the fan 300 through the above method, eliminating the need to disassemble the outer shell of the cabinet 100, thus facilitating easier fan 300 installation and removal.

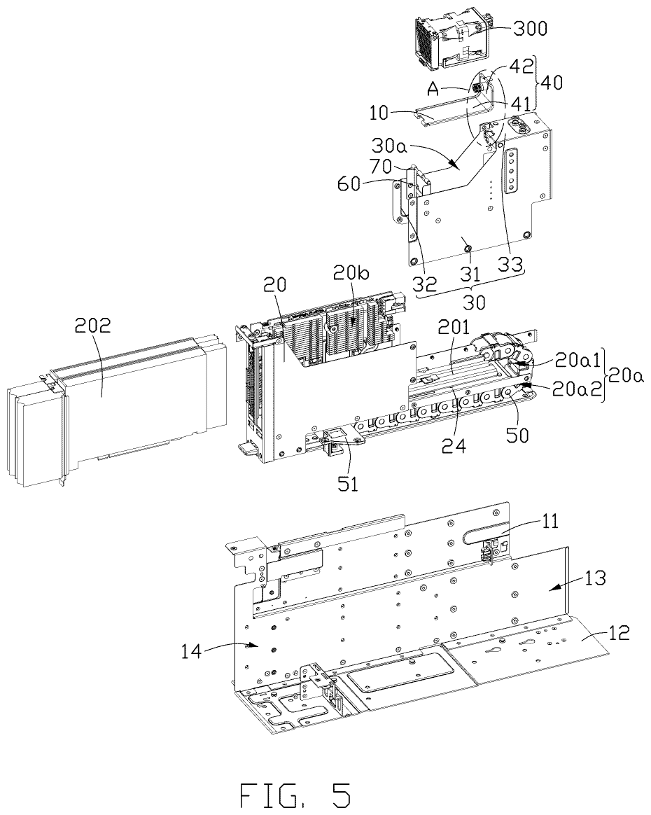

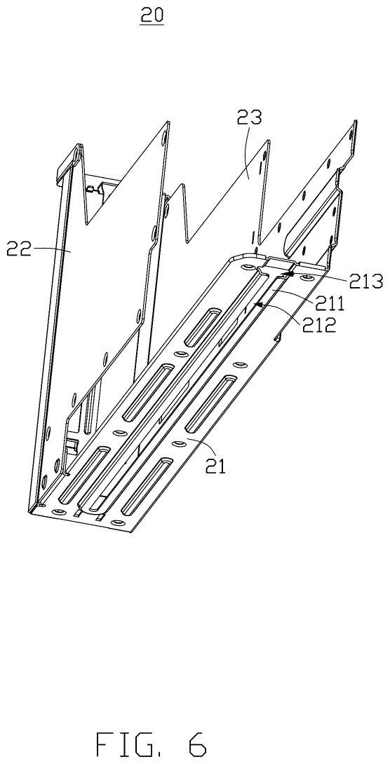

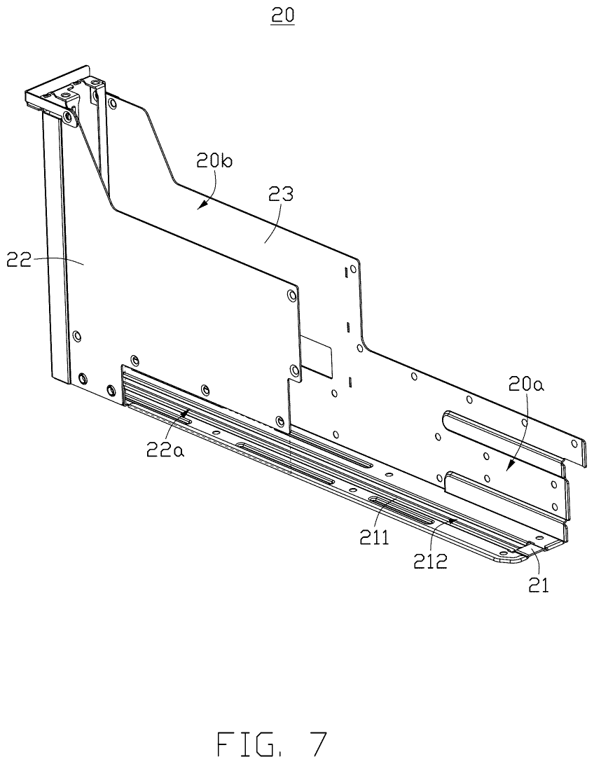

In some embodiments, referring to FIGS. 5 to 7, the front bracket part 20 includes a bottom board 21. The bottom board 21 protrudes toward the floor 12 to form a rib 211, and the rib 211 is provided with a sliding groove 212. The sliding groove 212 extends through a rear end of the rib 211 to form an entrance 213. The floor 12 is provided with multiple pins 121 arranged along the length of the rib 211, and the pins 121 can slide within the sliding groove 212. When the front bracket part 20 slides into or out of the chamber 13, the pins 121 can enter or exit the sliding groove 212 through the entrance 213. The head of the pin 121 is used for limiting the front bracket part 20, preventing the front bracket part 20 from detaching from the floor 12.

In some embodiments, the front bracket part 20 further includes a first board 22 and a second board 23. The first board 22 and the second board 23 are respectively connected to opposite sides of the bottom board 21. The first board 22 is the side of the front bracket part 20 away from the wall 11, and the second board 23 is the side of the front bracket part 20 close to the wall 11. The lower room 20a is formed between the bottom board 21, the first board 22, and the second board 23. The upper front room 20b is formed between the first board 22 and the second board 23. The rear bracket part 30 is installed on the rear side of the first board 22 and the second board 23. The length of the lower room 20a is greater than or equal to the combined length of the upper front room 20b and the upper rear room 30a. Since the expansion cards 201 are placed horizontally in the lower room 20a and the expansion cards 201 are relatively long, the hard drives 202 and the fan 300 are placed above the expansion cards 201, with the hard drives 202 in the front and the fan 300 in the rear, to improve space utilization.

In some embodiments, the front bracket part 20 is equipped with a partition board 24 in the lower room 20a. The partition board 24 divides the lower room 20a into an upper layer 20a1 and a lower layer 20a2. The expansion cards 201 are located in the upper layer 20a1 and are supported by the top surface of the partition board 24. The cabinet 100 further includes an articulated chain 50. One end of the articulated chain 50 extends from the rear end of the partition board 24 to the upper layer 20a1 and connects to the rear end of the expansion cards 201. The other end of the articulated chain 50 is located in the lower layer 20a2 and is fixed to the floor 12 through a fixing piece 51. The interior of the articulated chain 50 is used for accommodating cables of the expansion cards 201, and the cables are used for electrically connecting the expansion cards 201 to the motherboard. The bottom of the first board 22 is provided with a clearance slot 22a. The fixing piece 51 extends through the clearance slot 22a and is mounted to the floor 12 via screws. The clearance slot 22a allows the front bracket part 20 to avoid the fixing piece 51 during sliding, preventing interference.

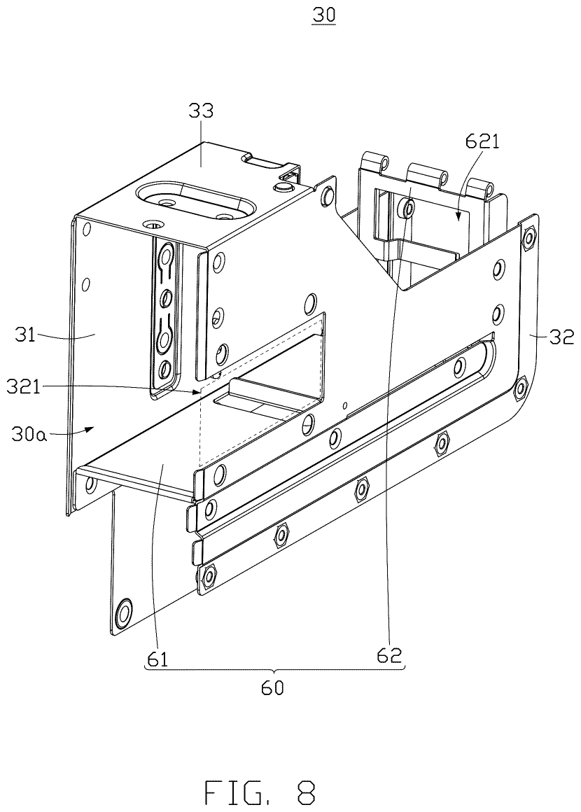

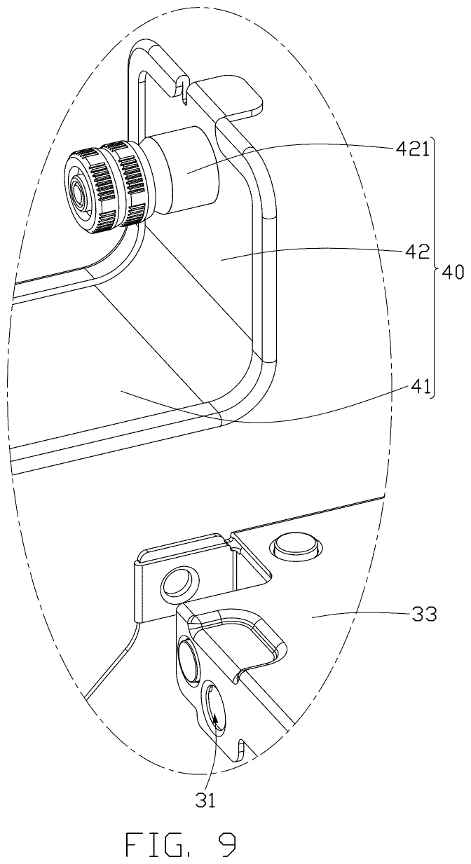

In some embodiments, referring to FIGS. 5, 8, and 9, the rear bracket part 30 includes a third board 31, a fourth board 32, and a top board 33. The third board 31 and the fourth board 32 are disposed on opposite sides of the top board 33. The third board 31 is mounted to the first board 22, and the fourth board 32 is mounted to the second board 23. The upper rear room 30a is formed between the third board 31 and the fourth board 32. The rear bracket part 30 is equipped with a rack 60 in the upper rear room 30a. The horizontal part 61 of the rack 60 is used for supporting the fan 300, and the vertical part 62 of the rack 60 is connected to the cover 40 via a shaft 70. The cover 40 can rotate around the shaft 70.

In some embodiments, the top board 33 is provided with a positioning hole 331. The cover 40 includes a press board 41 and a lock board 42 that are perpendicular to each other. The lock board 42 is provided with a latch 421. When the latch 421 is inserted into the positioning hole 331, the press board 41 presses down on the fan 300, securing the fan 300 against the horizontal part 61. When the latch 421 is disengaged from the positioning hole 331, the cover 40 can rotate around the shaft 70 to open the upper rear room 30a.

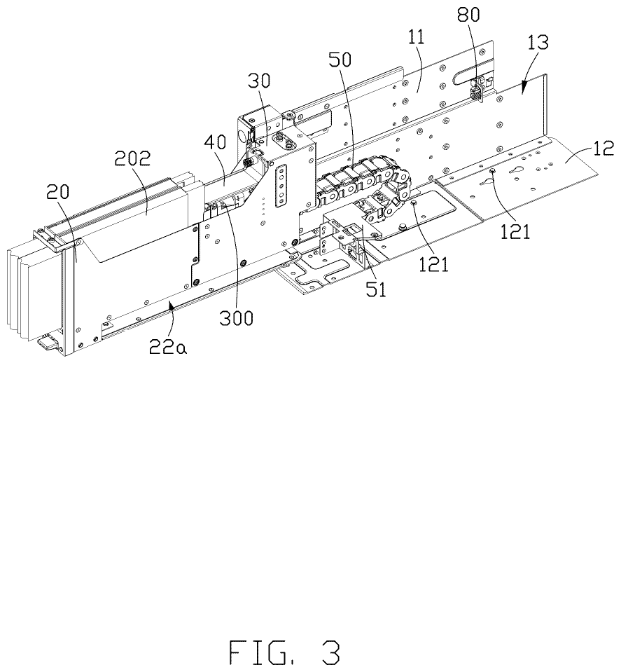

In some embodiments, referring to FIGS. 3, 4, and 8, the wall 11 is provided with a fan connector 80, and the fourth board 32 is provided with a notch 321 aligned with the fan connector 80. When the front bracket part 20 and the rear bracket part 30 slide into the chamber 13, the fan connector 80 automatically connects with the fan 300, powering the fan 300. The notch 321 is used for avoiding the fan connector 80, preventing interference between the fan connector 80 and the fourth board 32.

In some embodiments, the vertical part 62 is provided with a vent 621. The vent 621 allows airflow from the fan 300 to pass through the vertical part 62, enabling the fan 300 to dissipate heat for the hard drives 202.

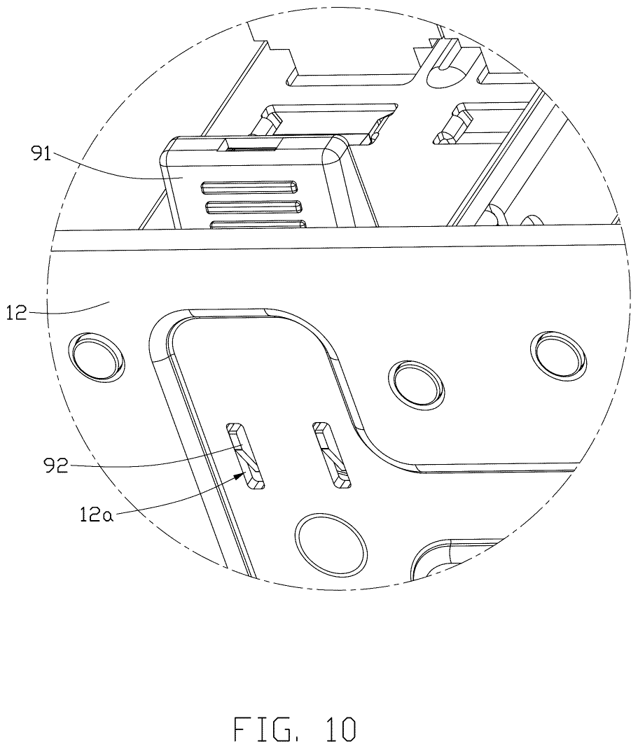

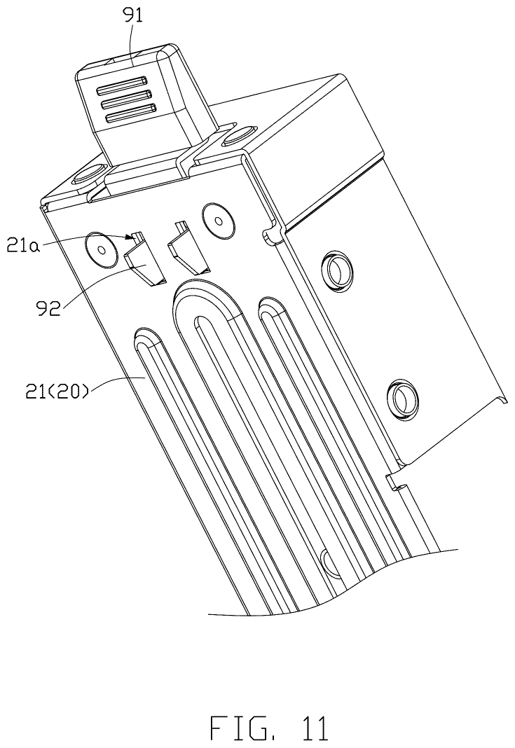

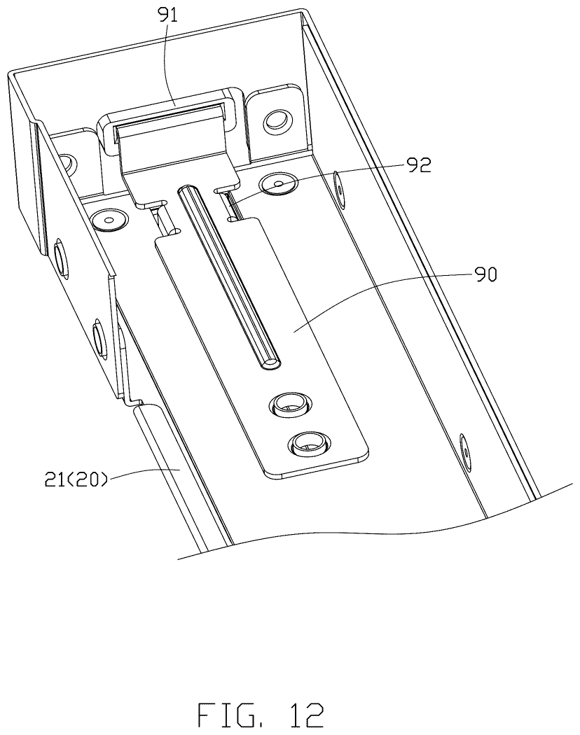

In some embodiments, referring to FIGS. 10 to 12, the bottom board 21 is provided with a first hole 21a, and the floor 12 is provided with a second hole 12a. The bottom board 21 is equipped with a leaf spring 90. One end of the leaf spring 90 is fixed to the bottom board 21, and the other end extends out of the opening 14 to form a handle 91. The leaf spring 90 is provided with an inserting sheet 92. When the front bracket part 20 slides into the chamber 13, the first hole 21a aligns with the second hole 12a, and the inserting sheet 92 passes through the first hole 21a and the second hole 12a to position the front bracket part 20. When the handle 91 is lifted by the user, the inserting sheet 92 disengages from the first hole 21a and the second hole 12a, allowing the front bracket part 20 to slide out of the chamber 13.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A cabinet of a server comprising:
a chassis comprising a chamber and an opening;
a bracket slidable into or out of the chamber through the opening, wherein a lower room, an upper front room, and an upper rear room are formed in the bracket, the lower room and the upper front room are configured for holding hardware, the upper rear room is configured for holding a fan; and
a cover rotatably mounted on the bracket for opening or covering the upper rear room, wherein when the bracket is slid out of the chamber, the cover is rotatable to open the upper rear room, such that the fan is detachable from the bracket for maintenance;
when the cover covers the upper rear room, the bracket is slidable into the chamber.

2. The cabinet of claim 1, wherein the chassis further comprises a wall and a floor, the chamber is formed in the chassis beside the wall, and the opening is formed at a front of the chassis, the bracket comprises a front bracket part and a rear bracket part, the front bracket part is slidably mounted on the floor, the lower room and the upper front room are formed in the front bracket part, the lower room is configured for holding expansion cards, the upper front room is configured for holding hard drives, the upper rear room is formed in the rear bracket part, the cover is rotatably mounted on a top of the rear bracket part.

3. The cabinet of claim 2, wherein the front bracket part comprises a bottom board, the bottom board protrudes toward the floor to form a rib, the rib is provided with a sliding groove, the sliding groove extends through an rear end of the rib to form an entrance, the floor is provided with a plurality of pins arranged along a length of the rib, the plurality of pins are slidable in the sliding groove, when the bracket slides, the plurality of pins enter or leave the sliding groove through the entrance, the plurality of pins are configured for guiding the front bracket part and limiting the front bracket part from leaving the floor.

4. The cabinet of claim 3, wherein the front bracket part further comprises a first board and a second board, the first board and the second board are respectively connected to opposite sides of the bottom board, the second board is between the wall and the first board, the lower room is enclosed by the bottom board, the first board, and the second board, the upper front room is between the first board and the second board, the rear bracket part is installed at a rear side of the first board and the second board, a length of the lower room is greater than or equal to a sum of a length of the upper front room and a length of the upper rear room.

5. The cabinet of claim 4, wherein the front bracket part comprises a partition board in the lower room, the partition board divides the lower room into an upper layer and a lower layer, the expansion cards are located in the upper layer and supported by the partition board, the cabinet further comprises an articulated chain, an end of the articulated chain extends from a rear of the partition board to the upper layer and connects to a rear end of the expansion cards, another end of the articulated chain is located in the lower layer and fixed to the floor by a fixing piece, the articulated chain is configured to accommodate cables of the expansion cards, a clearance slot is formed on the first board, the fixing piece extends out of the clearance slot to be fixed to the floor.

6. The cabinet of claim 4, wherein the rear bracket part comprises a third board, a fourth board, and a top board, the third board and the fourth board are arranged on opposite sides of the top board, the third board is mounted on the first board, the fourth board is mounted on the second board, the upper rear room is between the third board and the fourth board, the rear bracket part comprises a rack in the upper rear room, the rack comprises a horizontal part and a vertical part, the horizontal part supports the fan, the vertical part is provided with a shaft and the cover is rotatable around the shaft.

7. The cabinet of claim 6, wherein the top board is provided with a positioning hole, the cover comprises a press board and a lock board perpendicular to each other, the lock board comprises a latch, when the latch is inserted into the positioning hole, the press board presses the fan to the horizontal part, when the latch is pulled out of the positioning hole, the cover is released and rotatable around the shaft.

8. The cabinet of claim 6, wherein the wall is provided with a fan connector, the fourth board is provided with a notch, the notch is aligned with the fan connector, when the bracket is slid into the chamber, the fan connector is inserted into the notch and plugged into the fan to power the fan.

9. The cabinet of claim 6, wherein the vertical part is provided with a vent, the vent allows wind from the fan to pass through the vertical part for cooling the hardware.

10. The cabinet of claim 3, wherein the bottom board is provided with a first hole, the floor is provided with a second hole, the bottom board is provided with a leaf spring, an end of the leaf spring is fixed to the bottom board and another end extends out of the opening to form a handle, the leaf spring is provided with an inserting sheet, when the bracket is slid into the chamber, the first hole is aligned with the second hole, the inserting sheet passes through the first hole and the second hole to position the front bracket part; when the handle is lifted, the inserting sheet is pulled out of the first hole and the second hole, so that the bracket is slidable out of the chamber.

11. A server comprising:
a fan; and
a cabinet comprising:
a chassis comprising a chamber and an opening;
a bracket slidable into or out of the chamber through the opening, wherein a lower room, an upper front room, and an upper rear room are formed in the bracket, the lower room and the upper front room are configured for holding hardware, the upper rear room is configured for holding the fan; and
a cover rotatably mounted on the bracket for opening or covering the upper rear room, wherein when the bracket is slid out of the chamber, the cover is rotatable to open the upper rear room, such that the fan is detachable from the bracket for maintenance; when the cover covers the upper rear room, the bracket is slidable into the chamber, the fan is configured for cooling the hardware.

12. The server of claim 11, wherein the chassis further comprises a wall and a floor, the chamber is formed in the chassis beside the wall, and the opening is formed at a front of the chassis, the bracket comprises a front bracket part and a rear bracket part, the front bracket part is slidably mounted on the floor, the lower room and the upper front room are formed in the front bracket part, the lower room is configured for holding expansion cards, the upper front room is configured for holding hard drives, the upper rear room is formed in the rear bracket part, the cover is rotatably mounted on a top of the rear bracket part.

13. The server of claim 12, wherein the front bracket part comprises a bottom board, the bottom board protrudes toward the floor to form a rib, the rib is provided with a sliding groove, the sliding groove extends through an rear end of the rib to form an entrance, the floor is provided with a plurality of pins arranged along a length of the rib, the plurality of pins are slidable in the sliding groove, when the bracket slides, the plurality of pins enter or leave the sliding groove through the entrance, the plurality of pins are configured for guiding the front bracket part and limiting the front bracket part from leaving the floor.

14. The server of claim 13, wherein the front bracket part further comprises a first board and a second board, the first board and the second board are respectively connected to opposite sides of the bottom board, the second board is between the wall and the first board, the lower room is enclosed by the bottom board, the first board, and the second board, the upper front room is between the first board and the second board, the rear bracket part is installed at a rear side of the first board and the second board, a length of the lower room is greater than or equal to a sum of a length of the upper front room and a length of the upper rear room.

15. The server of claim 14, wherein the front bracket part comprises a partition board in the lower room, the partition board divides the lower room into an upper layer and a lower layer, the expansion cards are located in the upper layer and supported by the partition board, the cabinet further comprises an articulated chain, an end of the articulated chain extends from a rear of the partition board to the upper layer and connects to a rear end of the expansion cards, another end of the articulated chain is located in the lower layer and fixed to the floor by a fixing piece, the articulated chain is configured to accommodate cables of the expansion cards, a clearance slot is formed on the first board, the fixing piece extends out of the clearance slot to be fixed to the floor.

16. The server of claim 14, wherein the rear bracket part comprises a third board, a fourth board, and a top board, the third board and the fourth board are arranged on opposite sides of the top board, the third board is mounted on the first board, the fourth board is mounted on the second board, the upper rear room is between the third board and the fourth board, the rear bracket part comprises a rack in the upper rear room, the rack comprises a horizontal part and a vertical part, the horizontal part supports the fan, the vertical part is provided with a shaft and the cover is rotatable around the shaft.

17. The server of claim 16, wherein the top board is provided with a positioning hole, the cover comprises a press board and a lock board perpendicular to each other, the lock board comprises a latch, when the latch is inserted into the positioning hole, the press board presses the fan to the horizontal part, when the latch is pulled out of the positioning hole, the cover is released and rotatable around the shaft.

18. The server of claim 16, wherein the wall is provided with a fan connector, the fourth board is provided with a notch, the notch is aligned with the fan connector, when the bracket is slid into the chamber, the fan connector is inserted into the notch and plugged into the fan to power the fan.

19. The server of claim 16, wherein the vertical part is provided with a vent, the vent allows wind from the fan to pass through the vertical part for cooling the hardware.

20. The server of claim 13, wherein the bottom board is provided with a first hole, the floor is provided with a second hole, the bottom board is provided with a leaf spring, an end of the leaf spring is fixed to the bottom board and another end extends out of the opening to form a handle, the leaf spring is provided with an inserting sheet, when the bracket is slid into the chamber, the first hole is aligned with the second hole, the inserting sheet passes through the first hole and the second hole to position the front bracket part; when the handle is lifted, the inserting sheet is pulled out of the first hole and the second hole, so that the bracket is slidable out of the chamber.
